(19) United States
(12) Patent Application Publication
(10) Pub. No.: US 2023/0168304 A1
(43) Pub. Date: Jun. 1, 2023

(54) ARTIFICIAL INTELLIGENCE (AI)-BASED CHARGING CURVE RECONSTRUCTION AND STATE ESTIMATION METHOD FOR LITHIUM-ION BATTERY

(71) Applicant: BEIJING INSTITUTE OF TECHNOLOGY, Beijing (CN)

(72) Inventors: Rui XIONG, Beijing (CN); Jinpeng TIAN, Beijing (CN); Yanzhou DUAN, Beijing (CN)

(73) Assignee: BEIJING INSTITUTE OF TECHNOLOGY, Beijing (CN)

(21) Appl. No.: 17/916,041

(22) PCT Filed: Sep. 1, 2021
(86) PCT No.: PCT/CN2021/116036

§ 371 Date: Sep. 30, 2022

(30) Foreign Application Priority Data
Nov. 16, 2020 (CN) 202011281459.5

(51) Int. Cl. G01R 31/367; G01R 31/378; G01R 31/392

(52) U.S. Cl. CPC G01R 31/367; G01R 31/378; G01R 31/392

(57) ABSTRACT

An artificial intelligence (AI)-based charging curve reconstruction and state estimation method for a lithium-ion battery is provided to estimate various states of a battery. In the method, a complete charging curve is reconstructed through deep learning with charging data segments as input. Then, a plurality of states of the battery can be extracted from the complete charging curve, including a maximum capacity, maximum energy, a state of charge (SOC), a state of energy (SOE), a state of power (SOP), and a capacity increment curve. The battery charging curve reconstruction and state estimation method is adaptively updated with a change in a working state of the battery.

### CROSS REFERENCE TO THE RELATED APPLICATIONS

This application is the national phase entry of International Application No. PCT/CN2021/116036, filed on Sep. 1, 2021, which is based upon and claims priority to Chinese Patent Application No. 202011281459.5, filed on Nov. 16, 2020, the entire contents of which are incorporated herein by reference.

### TECHNICAL FIELD

The present disclosure relates to the field of battery systems and, in particular, to state estimation for a lithium-ion battery.

### BACKGROUND

During the actual operation of a lithium-ion battery, a battery management system can acquire only segments of signals, such as voltage, current, and temperature of the battery, and the internal states of the battery cannot be directly measured. The states of the battery can only be estimated based on the measured signals. In existing state estimation methods, only a few specific states can be estimated, and it is assumed that other states are known. Therefore, this is a great limitation on the global estimation. For example, the estimation of a battery capacity often focuses only on the establishment of a relationship between the capacity and features of a charging curve, while ignoring the estimation of other states. In fact, the battery charging curve (a relationship between the charging voltage and the charged capacity) reflects a large amount of battery state information and can meet the requirements of comprehensively and accurately representing the states of the battery. However, in practical application, the battery is often not fully charged and discharged, and the battery management system can acquire only part of the charging curve. Therefore, if a complete charging curve can be reconstructed through necessary technical means based on obtained accurate charging curve segments, it is of great significance to improve the battery state estimation method and battery management function.

### SUMMARY

In view of this, the present disclosure provides an artificial intelligence (AI)-based charging curve reconstruction and state estimation method for a lithium-ion battery, including the following steps:

Step 1: The complete voltage/current charging curve of a battery at different aging states in different charging manners is obtained as training data.

Step 2: The obtained charging curve is divided into data segments in an appropriate division manner, and the data segments and the charging curve are discretized.

Step 3: The selected deep learning algorithm is trained by using discretized data segments obtained in step 2, and the mapping relationship between the data segments and the complete charging curve is established.

Step 4: The trained deep learning algorithm is applied online. The actual charging data segments acquired by a battery management system are inputted into the deep learning algorithm. The complete charging curve is outputted.

Step 5: The battery state parameters to be estimated are extracted from the complete charging curve.

Further, the method includes:

Step 6: After the battery management system acquires a specific quantity of actual battery charging curves, the deep learning algorithm is retrained and updated.

Further, the step of obtaining the complete voltage/current charging curve of the battery at different aging states in different charging manners in step 1 specifically includes: charging the battery in common charging manners, such as constant current charging, constant current and constant voltage charging, multi-stage constant current charging, and pulse charging; and obtaining a daily charging curve of the battery at different aging states through battery testing and battery management system sampling, including battery charging current, voltage, and temperature signals in the corresponding charging manners.

Further, step 2 specifically includes: determining a segment length and sliding the segment length on the charging curve to divide the charging curve in step 1 into the data segments with the specific length, where the data segments each contain a sampled signal, such as a voltage, a current, or a temperature, at each moment; and sampling the obtained data segments at a fixed time interval or voltage interval to discretize the complete charging curve.

Further, the deep learning algorithm in step 3 is a convolutional neural network, a densely connected network, a recurrent neural network, or another type of network.

In the method provided in the present disclosure, the complete charging curve of the battery can be reconstructed through some charging segments. The maximum capacity, maximum energy, state of charge (SOC), state of energy (SOE), and state of power (SOP) can be estimated, and battery aging analysis can be implemented through a derived capacity increment curve, differential voltage curve, or another type of curve. In long-term applications, the algorithm can be continuously updated based on data output by the battery management system. This further improves the accuracy of charging curve reconstruction and state estimation.

### BRIEF DESCRIPTION OF THE DRAWINGS

FIG. 1 is a flowchart of a method according to the present disclosure;

FIG. 2 is a diagram of a preferred embodiment of the charging curve reconstruction according to the present disclosure;

FIG. 3 is a schematic diagram of the state estimation based on the charging curve reconstruction results in the present disclosure; and

FIG. 4 shows a capacity increment curve derived from a reconstituted charging curve.

### DETAILED DESCRIPTION OF THE EMBODIMENTS

The foregoing is merely an overview of the technical solutions of the present disclosure. To understand the technical means of the present disclosure more clearly, the present disclosure will be further described in detail below with reference to the accompanying drawings and specific embodiments.

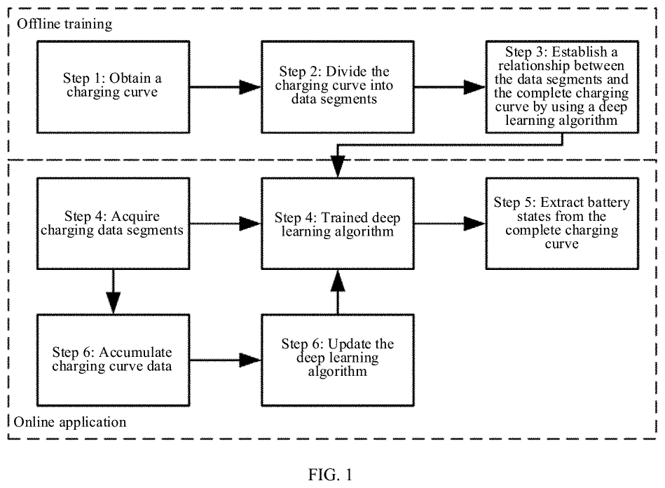

As shown in FIG. 1, an AI-based charging curve reconstruction and state estimation method for a lithium-ion battery provided in the present disclosure includes the following steps:

Step 1: A complete charging curve of a battery is obtained as training data by charging the battery in common charging manners, such as constant current charging, constant current and constant voltage charging, multi-stage constant current charging, and pulse charging. A daily charging curve of the battery is obtained at different aging states through battery testing, battery management system sampling, and others, including signals such as a charging current, voltage, and temperature of the battery in the given charging manners.

Step 2: The charging curve is divided into data segments, and the data segments and the charging curve are discretized by determining a segment length and sliding the segment length on the charging curve to divide the charging curve in step 1 into the data segments with the specific length. Each segment includes a sampled signal, such as a voltage, a current, or a temperature, at each moment. The obtained data segments are sampled at a fixed time interval or voltage interval to discretize the complete charging curve.

Step 3: A mapping relationship between the data segments and the complete charging curve is established by using a deep learning algorithm by selecting the deep learning algorithm, inputting discretized data segments obtained in step 2 into the algorithm, and outputting a discretized complete charging curve.

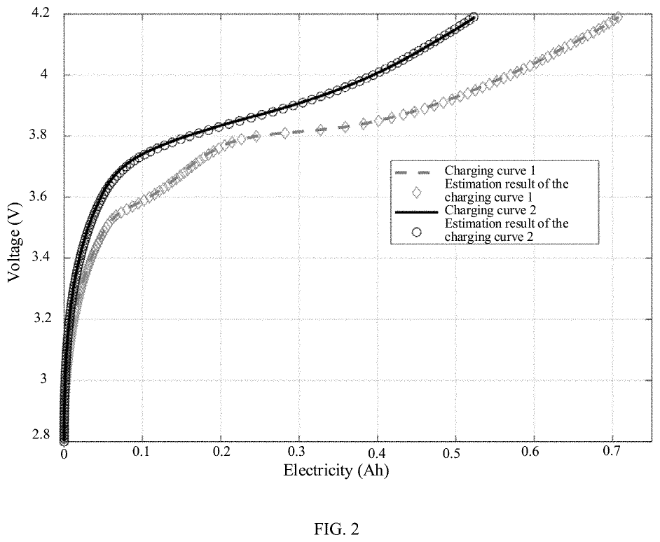

Step 4: In the actual application of the battery, charging data segments are acquired as input of the deep learning algorithm and a complete charging curve is outputted. During the actual operation of the battery, the battery management system acquires the charging data segments based on a segment division rule preset in step 2. The data segments are inputted into the deep learning algorithm trained in step 3 to obtain the estimated complete charging curve. In this embodiment, during the constant current charging of a ternary-material battery, a voltage window of 200 mV is used to obtain the charging segments, and a convolutional neural network is used to estimate the complete charging curve. FIG. 2 compares the charging curve reconstructed based on the present disclosure and the actual curve, which shows that the method can achieve high accuracy.

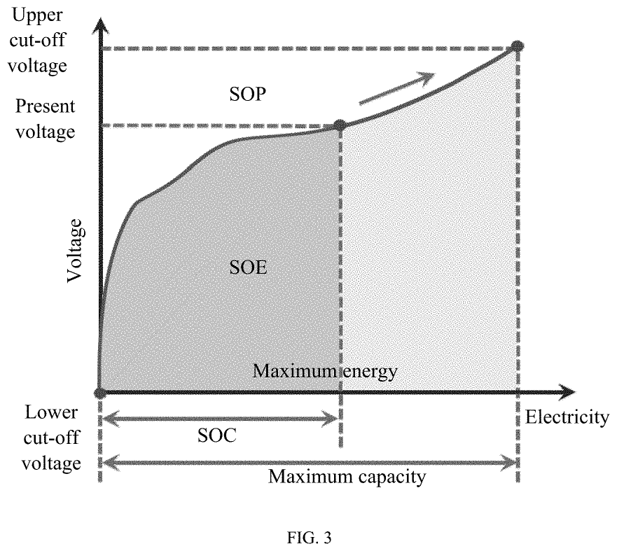

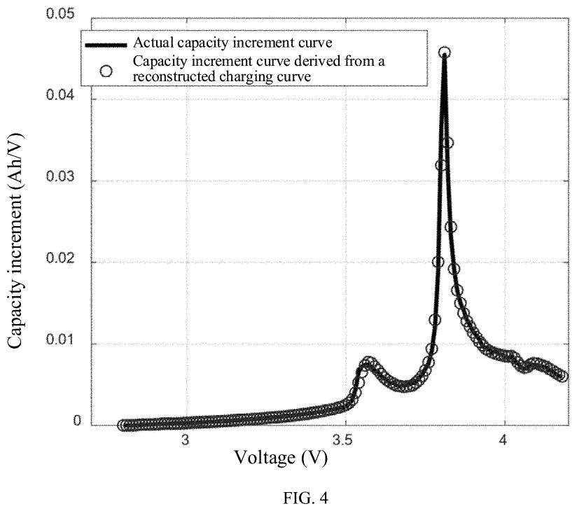

Step 5: The states of the battery are extracted from the complete charging curve. In the constant current charging curve shown in FIG. 3, the horizontal axis is the quantity of charged electricity, and the vertical axis is the battery voltage. After the complete charging curve is reconstructed, the quantity of electricity corresponding to the complete charging process of the battery from the lower cut-off voltage to the upper cut-off voltage is the maximum capacity of the battery. The integral of the voltage to the quantity of charged electricity in the charging process is the maximum energy of the battery (a sum of light and dark shades in the figure). In addition, the SOC of the battery, namely, the ratio of the quantity of electricity of the battery corresponding to the present voltage to the maximum capacity can be extracted based on the reconstructed complete charging curve. Similarly, an integral of the quantity of charged electricity from the lower cut-off voltage to the present voltage is the present energy of the battery (the dark shade in the figure), and the ratio of the current energy to the maximum energy of the battery is the SOE. Because the complete charging curve can be reconstructed through this method, the change in the voltage of the battery in the charging process can be predicted when the battery is not fully charged. In this way, the charging power, namely, the SOP of the battery can be evaluated. In addition, the reconstructed charging curve is differentiated, such that the capacity increment curve (the differential of the quantity of electricity to the voltage), the differential voltage curve (the differential of the voltage to the quantity of electricity), and others of the battery can be reconstructed through this method. This helps in the analysis of the internal mechanics of the battery. For example, the capacity increment curve obtained through this method is shown in FIG. 4.

Step 6: After a large quantity of battery charging curves is acquired, the algorithm is updated. After the battery runs for a period of time, the complete charging curve acquired by the battery management system is summarized through a data platform, and the deep learning algorithm in step 3 is updated by using the data as new training data. The method in steps 1 to 3 can be used to retrain the new deep learning algorithm, or some parameters of the previously trained algorithm are fine-tuned through transfer learning or the other like. In this way, the deep learning algorithm can be adaptively updated with the working states of the battery.

Although the embodiments of the present disclosure have been illustrated and described, it should be understood that those of ordinary skill in the art may make various changes, modifications, replacements, and variations to these embodiments without departing from the principle and spirit of the present disclosure, and the scope of the present disclosure is limited by the appended claims and their legal equivalents.

What is claimed is:

1. An artificial intelligence (AI)-based charging curve reconstruction and state estimation method for a lithium-ion battery comprising:
step 1: obtaining a complete voltage/current charging curve of a battery at different aging states in different charging manners as training data;
step 2: dividing the complete voltage/current charging curve into data segments in an appropriate division manner and discretizing the data segments and the complete voltage/current charging curve;
step 3: training a selected deep learning algorithm by using discretized data segments obtained in step 2 and establishing a mapping relationship between the data segments and the complete voltage/current charging curve;
step 4: applying a trained deep learning algorithm online, inputting actual charging data segments acquired by a battery management system into the trained deep learning algorithm, and outputting a complete charging curve; and
step 5: extracting battery state parameters to be estimated from the complete charging curve.

2. The AI-based charging curve reconstruction and state estimation method according to claim 1, further comprising:
step 6: after the battery management system acquires a specific quantity of actual battery charging curves, retraining and updating the deep learning algorithm.

3. The AI-based charging curve reconstruction and state estimation method according to claim 1, wherein the step of obtaining the complete voltage/current charging curve of the battery at different aging states in different charging manners in step 1 specifically comprises: charging the battery through constant current charging, constant current and constant voltage charging, multi-stage constant current charging, pulse charging, and others; and obtaining a daily charging curve of the battery at different aging states through battery testing and battery management system sampling, the daily charging curve comprising battery charging current, voltage, and temperature signals in the corresponding charging manners.

4. The AI-based charging curve reconstruction and state estimation method according to claim 1, wherein step 2 specifically comprises: determining a segment length and sliding the segment length on the complete voltage/current charging curve to divide the complete voltage/current charging curve obtained in step 1 into the data segments with the length, wherein the data segments each contains a sampled signal at each moment; and sampling the obtained data segments at a fixed time interval or voltage interval to discretize the complete voltage/current charging curve.

5. The AI-based charging curve reconstruction and state estimation method according to claim 1, wherein the deep learning algorithm in step 3 is a convolutional neural network, a densely connected network, or a recurrent neural network.
